(19) United States
(12) Patent Application Publication
(10) Pub. No.: US 2015/0262813 A1
(43) Pub. Date: Sep. 17, 2015

(54) SEMICONDUCTOR DEVICE

(71) Applicant: KABUSHIKI KAISHA TOSHIBA, Tokyo (JP)

(72) Inventors: Motoya KISHIDA, Kanazawa Ishikawa (JP); Yukie NISHIKAWA, Nonoichi Ishikawa (JP); Nobuhiro TAKAHASHI, Nonoichi Ishikawa (JP); Yasuhiko AKAIKE, Kanazawa Ishikawa (JP)

(21) Appl. No.: 14/473,791

(22) Filed: Aug. 29, 2014

(30) Foreign Application Priority Data
Mar. 17, 2014 (JP) 2014-053880

(51) Int. Cl. H01L 21/02; H01L 21/283; H01L 29/45; H01L 23/29; H01L 21/304; H01L 29/06; H01L 21/56; H01L 29/861; H01L 29/66

(52) U.S. Cl. CPC H01L 21/02118; H01L 29/861; H01L 21/283; H01L 29/45; H01L 29/6609; H01L 21/304; H01L 29/0684; H01L 21/56; H01L 23/293

(57) ABSTRACT

According to one embodiment, a semiconductor device includes a first electrode on a surface of a semiconductor layer and a plurality of second electrodes on the first electrode. Each second electrode has a shape in a plane that is parallel to the surface of the semiconductor layer having dimensions of 50 micrometers or less. A resin layer is between the plurality of second electrodes, and has a modulus that is lower than a modulus of the second electrodes.

### CROSS-REFERENCE TO RELATED APPLICATION

This application is based upon and claims the benefit of priority from Japanese Patent Application No. 2014-053880, filed Mar. 17, 2014, the entire contents of which are incorporated herein by reference.

### FIELD

Technology described herein generally relates to a semiconductor device.

### BACKGROUND

A semiconductor device for power control performs switching (ON/OFF) of a large electric current. In mounting such a semiconductor device, for example, there has been adopted a method where a bus bar is connected to electrodes of a semiconductor device via a solder sheet. Accordingly, in this semiconductor device, a thick-film electrode, to which Ni plating is applied, is used to suppress the erosion of solder. However, when the electrode is formed of a thick film, the wafer on which the semiconductor device is fabricated warps due to stress generated in the electrode, thus processing the wafer on manufacturing tools used in semiconductor device fabrication steps may be difficult because generally these tools require wafers of high flatness so as to generate uniform (or adequately so) processing results across the wafer. Furthermore, when a size of a chip is large an error in measurement by a chip tester becomes large due to warping of the chip, thus a manufacturing yield for the semiconductor device may be unacceptably low.

### DESCRIPTION OF THE DRAWINGS

FIG. 1A and FIG. 1B are schematic views of a semiconductor device according to a first embodiment.

FIG. 2A and FIG. 2B are schematic cross-sectional views which illustrate manufacturing steps of the semiconductor device according to the first embodiment.

FIG. 3A and FIG. 3B are schematic cross-sectional views which illustrate manufacturing steps subsequent to the manufacturing step illustrated in FIG. 2B.

FIG. 4A and FIG. 4B are schematic cross-sectional views which illustrate manufacturing steps subsequent to the manufacturing steps illustrated in FIG. 3B.

FIG. 5A and FIG. 5B are schematic views of the electrode structure of the semiconductor device according to the first embodiment.

### DETAILED DESCRIPTION

An example embodiment provides a semiconductor device with suppressed wafer and chip warping, thus the semiconductor device will have improved manufacturing yield.

A semiconductor device of an example embodiment comprises a first electrode on a surface of a semiconductor layer and a plurality of second electrodes on the first electrode. Each second electrode has a shape in a plane that is parallel to the surface of the semiconductor layer that has dimensions of 50 micrometers or less. A resin layer is provided between the plurality of second electrodes, and has a modulus that is lower than a modulus of the plurality of second electrodes.

In general, according to one embodiment, a semiconductor device includes: a semiconductor layer; a first electrode that is formed on a front surface of the semiconductor layer; a plurality of second electrodes that are formed on the first electrode, a cross-section of each second electrode parallel to the front surface of the semiconductor layer having a rectangular shape with a side size of 50 micrometers or less; and a resin layer that is formed between the plurality of second electrodes, and has a ductility higher than a ductility of the second electrode.

Hereinafter, an embodiment is explained by reference to drawings. Identical portions illustrated in the drawings are given the same symbols, and the detailed explanation of the identical portions is omitted and only different portions are explained when appropriate. The drawings are schematic or conceptual views and hence, the relationship between thicknesses and widths of respective portions, ratio of sizes of the respective portions and the like are not always equal to those of an actual semiconductor device. Further, even when the identical portions are described in the drawings, sizes or ratios of sizes of the portions may differ in accordance with drawings.

The arrangement and the configuration of respective portions are explained using the X axis direction, the Y axis direction and the Z axis direction of an XYZ orthogonal coordinate system illustrated in the respective drawings. There may be the case where the explanation is made assuming that one side in the Z axis direction is set as an upper side and the other side in the Z axis direction is set as a lower side. However, this is not necessarily a limitation, and in some embodiments the upper side and lower side may be reversed.

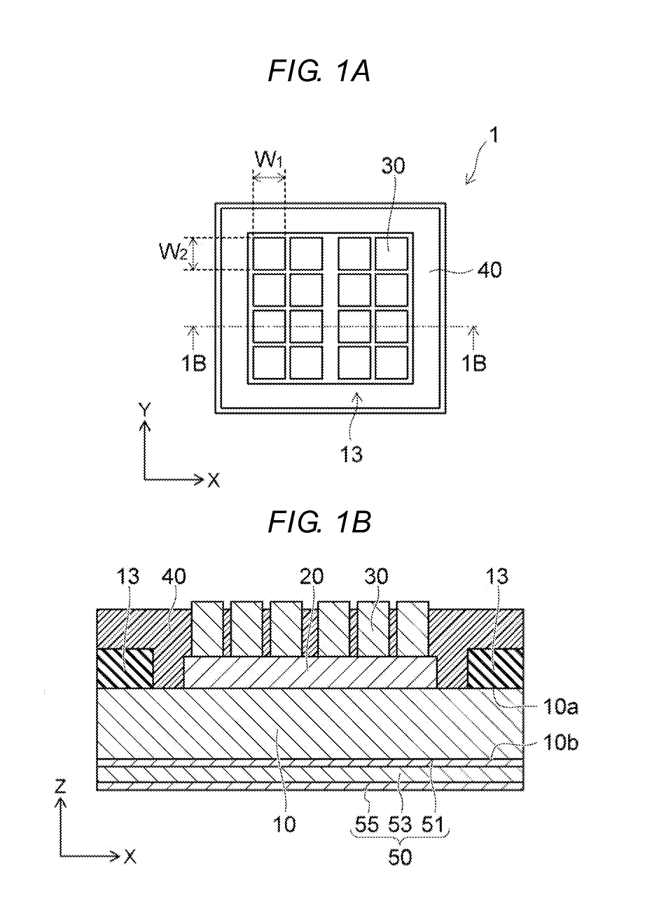

FIG. 1A and FIG. 1B are schematic views which exemplify a semiconductor device 1 according to an example first embodiment. That is, FIG. 1A is the schematic plan view which exemplifies an upper surface of a chip of the semiconductor device 1, and FIG. 1B is a cross-sectional view taken along a line 1B-1B in FIG. 1A.

The semiconductor device 1 includes: a semiconductor layer 10; a first electrode 20 which is formed on a front surface 10a of the semiconductor layer 10; and a plurality of second electrodes 30 which are formed on the first electrode 20. The semiconductor device 1 also includes a resin layer 40 which is formed between the plurality of second electrodes 30.

As illustrated in FIG. 1A, the second electrodes 30 are formed such that each second electrode 30 has a rectangular shape when viewed from a front surface side of the semiconductor layer 10, for example. In other words, the second electrode 30 is formed such that a cross-sectional shape of the second electrode 30 parallel to the front surface 10a of the semiconductor layer 10 is a rectangular shape. Further, both a width W₁ of one side of the cross-sectional shape and a width W₂ of another side of the cross-sectional shape are set to 50 micrometers (μm) or less, for example, respectively. A resin having a higher ductility (lower modulus of elasticity) than the second electrode 30 is used for forming the resin layer 40, for example.

The semiconductor device 1 includes a Fast Recovery Diode (FRD) used in a power control circuit, for example. As illustrated in FIG. 1A, the plurality of second electrodes 30 are formed on the center of a chip surface of the semiconductor device 1. Since the FRD is required to possess a high breakdown voltage characteristic, a guard ring structure 13 (first ring structure) which surrounds the plurality of second electrodes is formed on an outer periphery of the chip surface.

As illustrated in FIG. 1B, the semiconductor device 1 includes the semiconductor layer 10. The semiconductor layer 10 is formed of an n-type silicon substrate or an n-type silicon layer formed on the silicon substrate, for example.

For example, a thickness of the semiconductor layer 10 in the Z axis direction is 115 μm. A thickness of a silicon wafer used in the manufacture of the semiconductor device 1 is 270 μm, for example, and the thickness of the silicon wafer is reduced by grinding or etching during fabrication of the semiconductor device 1. The FRD is required to possess a low recovery loss, a high-speed performance (high switching speed) and the like together with a high breakdown voltage characteristic. In general, there exists a trade-off relationship between a forward voltage Vf of the FRD and a recovery loss, however the trade-off relationship may be improved by decreasing the thickness of the semiconductor layer 10.

A p-type anode layer not specifically illustrated in the drawing is formed on a front surface 10a side of the semiconductor layer 10, for example. The first electrode 20 is formed on the p-type anode layer. The first electrode 20 is formed of an aluminum film, for example, and is in ohmic contact with the p-type anode layer. The first electrode 20 is not limited to an aluminum film, and in some embodiments may be formed such that the first electrode 20 has the structure where a titanium (Ti) layer and a titanium nitride (TiN) layer are laminated to each other, for example. In this case, the titanium layer is brought into contact with the p-type anode electrode.

The plurality of second electrodes 30 are formed on the first electrode 20. In the FRD, a nickel electrode which is formed of a thick film and has nickel plating thereon is applied to a surface of the chip so as allow the FRD to cope with a high current density and a double-surface cooling structure, for example. The second electrodes 30 correspond to this nickel electrode. The second electrodes 30 have a thickness of at least 4 μm after taking into account the erosion of solder during mounting the second electrodes 30 on the first electrode 20, for example.

In this embodiment, the nickel electrode is formed on the first electrode 20 in a state where the nickel electrode is divided into the plurality of second electrodes 30. Due to such a configuration, warping of a wafer in manufacturing steps of the semiconductor device 1 may be decreased.

For example, when the second electrode 30 is formed of a single (full plane) nickel electrode, warping of 300 μm or more is typically generated in a silicon wafer having a diameter of 8 inches. Further, a chip size of an FRD having a breakdown voltage of 600 to 800 V is approximately 10 mm and hence, chip warping of approximately 80 μm to 120 μm is generated, for example.

When such large warping occurs, a failure such as an error in carrying/handling a wafer within a processing tool or a failure (e.g., severe chip-to-chip non-uniformity) in the treatment of the wafer occurs in an ion implantation device, a pretreatment device, a heat treatment device or the like which is used in the manufacture of the semiconductor device 1. Furthermore, warping of the chip may cause an error in handling the chip due to an image recognition failure or cause an error in device characteristic measurements due to a contact failure between the warped chip and a stage/chuck in a chip testing tool. It may also be that warping of the chip causes an assembly failure due to insufficient wetting of solder along the warped chip high spots during mounting the chip.

According to this example, the second electrodes 30 which are obtained by dividing one electrode into a plurality of electrodes are formed on the first electrode 20 and hence, it is possible to suppress a warping amount of a chip to 50 μm or less, for example. Similarly, warping of a wafer is also suppressed. Accordingly, the failures which may be caused in the above-mentioned wafer process, a chip test, and chip mounting on severely warped chips may be obviated.

The second electrode 30 is formed such that a cross-sectional shape of a cross section (X-Y plane) of the second electrode 30 parallel to the front surface 10a of the semiconductor layer 10 is a rectangular shape, for example. It is desirable that the rectangular cross section has a width W₁ of 50 μm or less in the X axis direction and a width W₂ of 50 μm or less in the Y axis direction, respectively. For example, in forming a rectangular metal film having a thickness of 4 μm or more on the silicon substrate, in a region where a length of a side of the rectangular metal film is set to 50 μm or less, a stress generated between the metal film and the silicon substrate is unexpectedly decreased.

Furthermore, the resin layer 40 is formed between the plurality of second electrodes 30. As illustrated in FIG. 1B, the resin layer 40 covers the entire surface of the chip except for the second electrodes 30. Due to such a configuration, for example, it is possible to prevent solder from intruding into the first electrode 20 and the semiconductor layer 10 upon connecting a bus bar to the second electrodes 30 via a solder sheet.

The resin layer 40 may preferably be formed using a material such as polyimide having a higher ductility (lower modulus of elasticity—that is, has greater flexibility) than that of a material for forming the second electrode 30. By forming the resin layer 40 using such a material, the resin layer 40 may decrease warping of a wafer by absorbing a stress caused by the second electrodes 30.

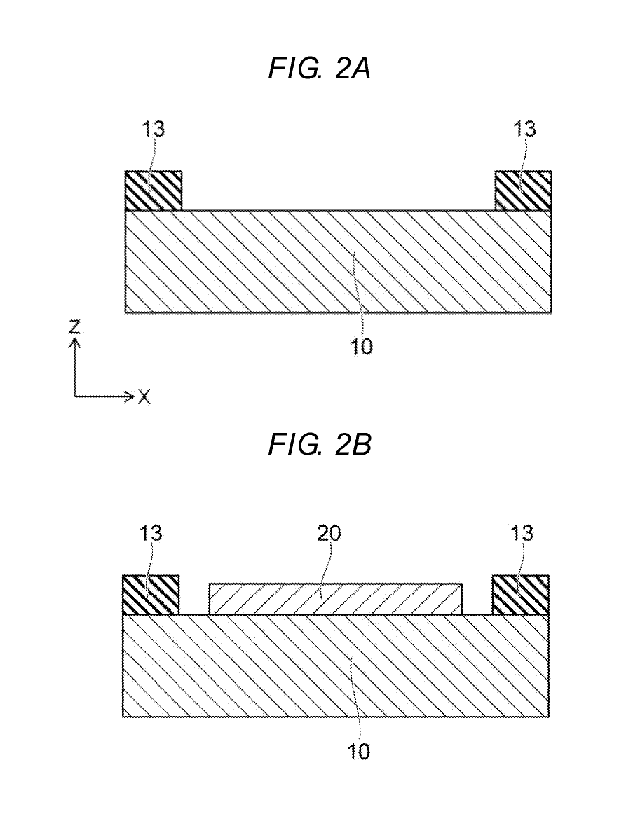

Next, a method of manufacturing the semiconductor device 1 according to the embodiment is explained by reference to FIG. 2A to FIG. 4B. FIG. 2A to FIG. 4B are schematic cross-sectional views which exemplify manufacturing steps of the semiconductor device 1 according to the embodiment.

As illustrated in FIG. 2A, a wafer having the semiconductor layer 10 and the guard ring structure 13 formed on the semiconductor layer 10 is prepared. The semiconductor layer 10 is formed of an n-type silicon layer or an n-type silicon wafer, for example.

A p-type anode layer (not specifically illustrated in the drawing) which is selectively doped with a p-type dopant by ion implantation is formed in the semiconductor layer 10 within the guard ring structure 13. A guard ring diffusion layer (not specifically illustrated in the drawing) is formed in the semiconductor layer 10 below the guard ring structure 13. The p-type anode layer and the guard ring diffusion layer are formed in such a manner that boron which is injected into the semiconductor layer 10 by ion implantation is activated by heat treatment so that boron is diffused into the semiconductor layer 10.

Next, as illustrated in FIG. 2B, an aluminum film is formed on the p-type anode layer using a sputtering method, for example, to form the first electrode 20. As one example of the guard ring structure 13, a field plate electrode formed of an aluminum film may be formed on the guard ring diffusion layer. A material for forming the first electrode 20 is not limited to aluminum (Al) and, for example, an alloy such as aluminum copper (AlCu) or aluminum silicon (AlSi) may be used as such a material. After the first electrode 20 is formed, heat treatment is applied to the above-mentioned structure at a temperature of 420° C. for 30 minutes to make ohmic contact between the p-type anode layer and the first electrode 20.

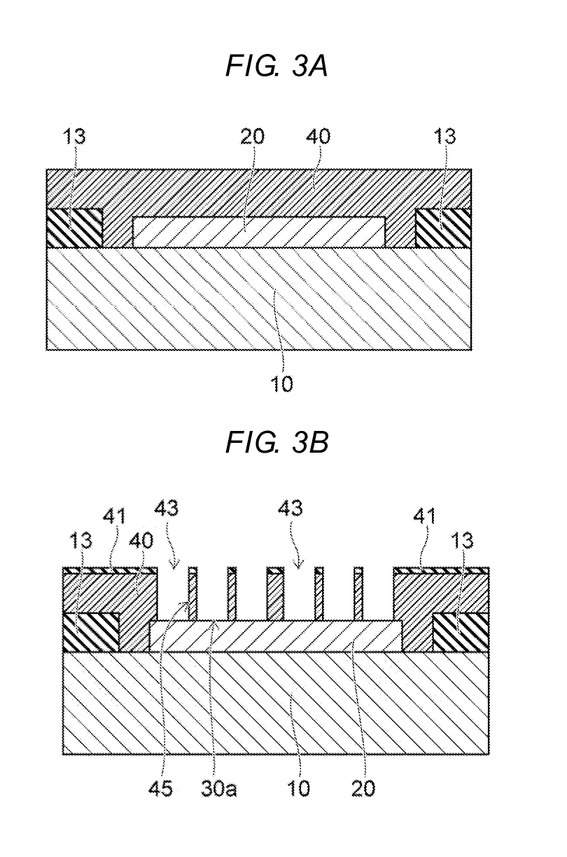

Next, as illustrated in FIG. 3A, the resin layer 40 which covers the semiconductor layer 10, the first electrode 20 and the guard ring structure 13 is formed. The resin layer 40 is formed of a polyimide film, for example.

Subsequently, as illustrated in FIG. 3B, a mask 41 is formed on the resin layer 40, and patterning is applied to the resin layer 40. The mask 41 is formed of a silicon oxide film, for example, and has a plurality of openings 43 above the first electrode 20. Each opening 43 is formed into a rectangular shape, for example, and a length of each side of the opening 43 is 50 μm or less. The resin layer 40 is etched using the mask 41 to form openings 45 which extend to the first electrode 20.

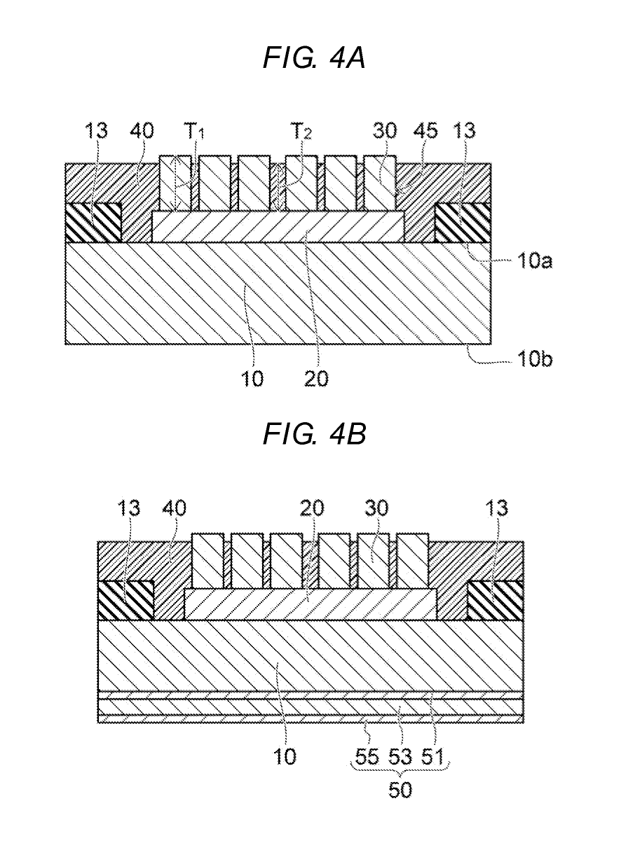

Next, as illustrated in FIG. 4A, nickel electroless plating is applied to the substrate 10 using the resin layer 40 having the openings 45 to form the second electrodes 30 in the inside of the openings 45, for example. A thickness T₁ of the second electrode 30 in the Z axis direction is 4 μm, for example. A thickness T₁ of the second electrode 30 is larger than a thickness T₂ of the resin layer 40 formed on the first electrode 20 in the Z axis direction. That is, the second electrodes 30 are formed such that the second electrodes 30 project from the resin layer 40 in the Z axis direction. After performing nickel plating to form the second electrodes 30, a thin layer (e.g., 25 nm) made of gold may be formed on upper surfaces of the second electrodes 30 by applying gold (Au) plating. Such gold plating suppresses the oxidation of nickel so that wettability of the second electrodes 30 with solder may be enhanced.

Next, a rear surface side of the wafer on a side opposite to a front surface 10a of the semiconductor layer 10 is ground to decrease a thickness of the semiconductor layer 10 to a desired thickness. Then, phosphorus (P), which is an n-type dopant, is injected into a rear surface 10b side of the semiconductor layer by ion implantation to form an n-type high-concentration layer. The n-type dopant is activated and diffused by laser annealing, for example.

Furthermore, a third electrode 50 is formed on a rear surface 10b of the semiconductor layer 10. The third electrode 50 includes in this example: a titanium film 51 having a thickness of 200 nanometers (nm) which is laminated on the rear surface 10b; a nickel film 53 having a thickness of 700 nm; and a gold-tin alloy film 55 having a thickness of 100 nm. The third electrode 50 is formed by laminating the titanium film 51, the nickel film 53 and the gold-tin alloy film 55 in this order by a sputtering method, for example.

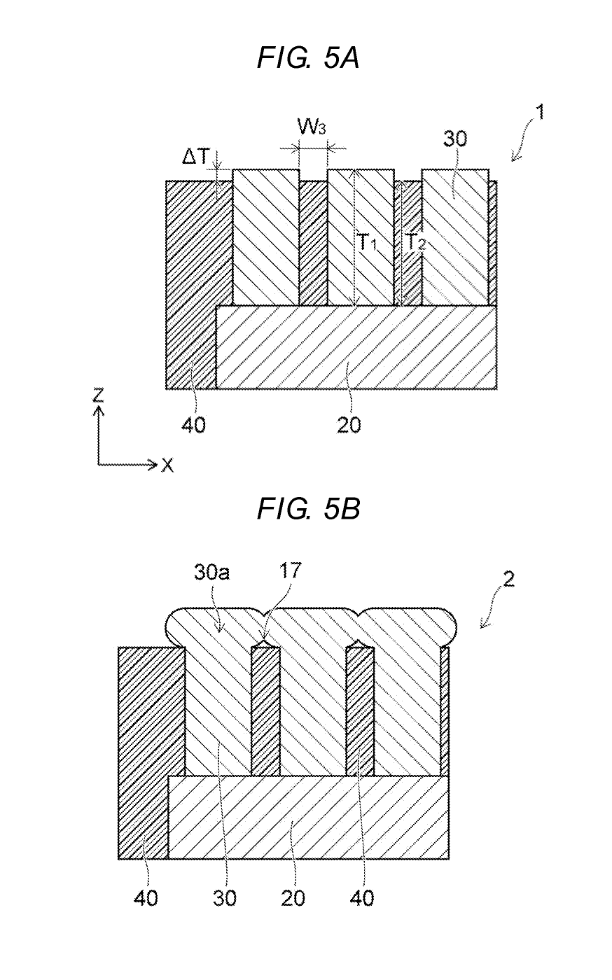

FIG. 5A is a schematic view which exemplifies the electrode structure of the semiconductor device 1 according to the first embodiment. FIG. 5B is a schematic view which exemplifies the electrode structure of a semiconductor device 2 according to a comparison example.

In FIG. 5A, for example, ΔT is defined as a difference between the thickness T₁ of the second electrode 30 in the Z axis direction and the thickness T₂ of the resin layer 40 in the Z axis direction. It has been determined that is preferable that ΔT is smaller than a distance W₃ between two second electrodes 30 adjacent to each other.

In the semiconductor device 2 illustrated in FIG. 5B, the second electrodes 30 are formed such that ΔT is larger than the distance W₃. Due to such a configuration, as illustrated in FIG. 5B, projecting portions 30a of the second electrodes 30 which project from the resin layer 40 spread in the X axis direction, for example, and two second electrodes 30 arranged adjacent to each other are connected to each other at the projecting portions 30a. In this case, it may be that a stress generated between the plurality of second electrodes 30 which are connected to each other via the projecting portion 30a increases warping of the wafer. It may be also that a plating solution or the like remains in a gap 17 formed between the projecting portions 30a arranged adjacent to each other, and the remained plating solution may cause contamination in sequent steps.

However, in the first embodiment, ΔT is set smaller than the distance W₃ so that warping of a wafer may be decreased, and the contamination of the wafer may be avoided.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a conductive material on a surface of a semiconductor layer;
a plurality of electrodes on the conductive material, each electrode having a shape in a plane that is parallel to the surface of the semiconductor layer with dimensions of 50 micrometers or less; and
a resin layer between the plurality of electrodes, and having a modulus that is lower than a modulus of the plurality of electrodes.

2. The semiconductor device according to claim 1, wherein a thickness of the electrodes in a first direction orthogonal to the surface of the semiconductor layer is greater than a thickness of the resin layer in the first direction.

3. The semiconductor device according to claim 1, wherein the shape of each electrode is rectangular in the plane.

4. The semiconductor device according to claim 3, wherein a distance between adjacent electrodes in a direction parallel to the plane is greater than a difference between a thickness of the electrodes in a direction orthogonal to the plane and a thickness of the resin layer in the direction orthogonal to the plane.

5. The semiconductor device according to claim 1, wherein a distance between adjacent electrodes in a direction parallel to the plane is greater than a difference between a thickness of the electrodes in a direction orthogonal to the plane and a thickness of the resin layer in the direction orthogonal to the plane.

6. The semiconductor device according to claim 1, further comprising:
a first ring structure formed on the semiconductor layer and surrounding the plurality of electrodes in the plane.

7. The semiconductor device according to claim 1, wherein the resin layer comprises a polyimide.

8. The semiconductor device according to claim 7, wherein the conductive material comprises aluminum and the plurality of electrodes comprises nickel.

9. The semiconductor device according to claim 1, wherein the conductive comprises aluminum and the plurality of electrodes comprises nickel.

10. A semiconductor device, comprising:
a semiconductor layer;
a first electrode that is provided on a surface of the semiconductor layer;
a plurality of second electrodes that are provided on the first electrode, a cross-section of each second electrode in a plane parallel to the surface of the semiconductor layer having a rectangular shape; and
a resin layer between the plurality of second electrodes, and having a lower modulus than the second electrode, wherein
a thickness of the resin layer in a first direction orthogonal to the surface of the semiconductor layer is less than a thickness of the second electrode in the first direction.

11. The semiconductor device according to claim 10, wherein a distance between adjacent second electrodes in a second direction parallel to the surface of the semiconductor layer is greater than a difference between the thickness of the second electrode in the first direction orthogonal to the surface of the semiconductor layer and the thickness of the resin layer in the first direction.

12. The semiconductor device according to claim 10, wherein the resin layer comprises polyimide.

13. The semiconductor device according to claim 10, wherein the first electrode comprises aluminum and the plurality of second electrodes comprise nickel.

14. The semiconductor device according to claim 10, wherein the semiconductor device is a diode.

15. A method of manufacturing a semiconductor device, the method comprising:
forming a semiconductor layer;
forming a first conductive material on the semiconductor layer;
forming a resin layer on the first conductive material and the semiconductor layer;
forming a plurality of openings through the resin layer to the first conductive material; and
forming a second conductive material in the plurality of openings through the resin layer, a thickness of the second conductive material in a first direction orthogonal to the semiconductor layer being greater than a thickness of the resin layer in the first direction, wherein
a distance in a second direction between adjacent openings of the plurality of openings is greater than a difference between the thickness of the second conductive material and the thickness of the resin layer.

16. The method of claim 15, further comprising:
decreasing a thickness of the semiconductor layer by grinding.

17. The method of claim 15, wherein the first metal film comprises aluminum, the second metal film comprises nickel, and the resin layer comprises polyimide.

18. The method of claim 15, further comprising:
depositing a metal on the second conductive material, wherein the second conductive material comprises nickel and the metal film comprises gold.

19. The method of claim 15, wherein the openings in the resin layer are rectangular and have width and a length in a plane that is parallel to the surface of the semiconductor layer of 50 micrometers or less.

20. The method of claim 15, wherein the semiconductor device is a diode.
